(19) United States
(12) Patent Application Publication
(10) Pub. No.: US 2025/0287705 A1
(43) Pub. Date: Sep. 11, 2025

(54) LIGHTWEIGHT, IMPACT-RESISTANT PHOTOVOLTAIC MODULE

(71) Applicant: COMMISSARIAT A L'ENERGIE ATOMIQUE ET AUX ENERGIES ALTERNATIVES, PARIS (FR)

(72) Inventors: Julien GAUME, GRENOBLE (FR); Benjamin COMMAULT, GRENOBLE (FR); Maria PLANELLS VALENCIA, GRENOBLE (FR); Yannick VESCHETTI, GRENOBLE (FR)

(73) Assignee: COMMISSARIAT A L'ENERGIE ATOMIQUE ET AUX ENERGIES ALTERNATIVES, PARIS (FR)

(21) Appl. No.: 18/857,386

(22) PCT Filed: Mar. 22, 2023
(86) PCT No.: PCT/FR2023/050412

§ 371 Date: Oct. 16, 2024

(30) Foreign Application Priority Data
Apr. 20, 2022 (FR) FR2203624

(51) Int. Cl. H10F 19/80; H10F 19/85

(52) U.S. Cl. CPC H10F 19/804; H10F 19/807; H10F 19/85

(57) ABSTRACT

The invention primarily relates to a photovoltaic module (1) obtained from a stack comprising: a first front layer (2); a plurality of photovoltaic cells (4); an encapsulating assembly (3) obtained by joining a front layer (3a) and a rear layer (3b) of an encapsulating material; a second rear layer (5). The first layer (2) comprises: a front layer made of a polymer material (2a); a front assembly (2b, 2c) comprising an interface front layer (2b) and a glass front layer (2c), with a thickness less than or equal to 2 mm, said front assembly (2b, 2c) being located between the polymer front layer (2a) and the encapsulating assembly (3), and the interface front layer (2b) being located between the polymer front layer (2a) and the glass front layer (2c). The front layer (3a) and the rear layer (3b) of an encapsulating material have a Young's modulus at 25° C. of strictly less than 50 MPa and of strictly greater than 150 Mpa, respectively.

### TECHNICAL FIELD

The present invention relates to the field of photovoltaic modules, which include a set of photovoltaic cells electrically connected to each other, and preferably photovoltaic cells called “crystalline” photovoltaic cells, that is to say which are based on monocrystalline or multicrystalline silicon.

The invention can be implemented for many applications, in particular civil and/or military, for example autonomous and/or embedded applications, being particularly concerned with applications which require the use of lightweight photovoltaic modules, in particular with a weight per unit area of less than 5 kg/m², or even 6 kg/m², in particular intended to be fixed on a rigid support resistant to hail-type impacts according to standard IEC 61215. It can thus in particular be applied to buildings such as homes or industrial premises (tertiary, commercial, etc.), for example for the construction of their roofs, for the design of street furniture, for example for public lighting, road signs or else the recharging of electric cars, or even be used for nomadic applications (solar mobility), in particular for integration on vehicles, such as cars, buses or boats, among others.

The invention thus proposes a lightweight photovoltaic module obtained by a stack including a first glass and polymer layer forming the front face of the module, as well as a method for producing such a photovoltaic module.

### PRIOR ART

A photovoltaic module is an assembly of photovoltaic cells disposed side by side between a first transparent layer forming a front face of the photovoltaic module and a second layer forming a rear face of the photovoltaic module.

The first layer forming the front face of the photovoltaic module is advantageously transparent to allow the photovoltaic cells to receive a luminous flux. It is conventionally made of a single glass plate, in particular tempered glass, with a thickness typically comprised between 2 and 4 mm, conventionally of the order of 3 mm.

The second layer forming the rear face of the photovoltaic module can in turn be made from glass, metal or plastic, among others. It is often formed by a polymer structure based on an electrically insulating polymer, for example of the polyethylene terephthalate (PET) or polyamide (PA) type, which can be protected by one or more layers based on fluorinated polymers, such as polyvinyl fluoride (PVF) or polyvinylidene fluoride (PVDF), and with a thickness of the order of 300 μm.

The photovoltaic cells can be electrically connected to each other by front and rear electrical contact elements, called connecting conductors, and formed for example by strips of tinned copper, respectively disposed against the front faces (faces opposite the front face of the photovoltaic module intended to receive a luminous flux) and rear faces (faces opposite the rear face of the photovoltaic module) of each of the photovoltaic cells, or else only on the rear face for IBC (for “Interdigitated Back Contact”) type photovoltaic cells.

It should be noted that IBC (“Interdigitated Back Contact”) type photovoltaic cells are structures for which the contacts are made on the rear face of the cell in the form of interdigitated combs. They are for example described in American patent U.S. Pat. No. 4,478,879 A.

Moreover, the photovoltaic cells, located between the first and second layers forming respectively the front and rear faces of the photovoltaic module, can be encapsulated. Conventionally, the chosen encapsulant corresponds to a polymer of the elastomer (or rubber) type, and can for example consist of the use of two layers (or films) of poly (ethylene-vinyl acetate) (EVA) between which the photovoltaic cells and the cell connection conductors are disposed. Each layer of encapsulant can have a thickness of at least 0.2 mm and a Young's modulus typically comprised between 2 and 400 MPa at room temperature.

A conventional example of a photovoltaic module 1 including crystalline photovoltaic cells 4 was thus partially and schematically represented, respectively in section in FIG. 1 and in exploded view in FIG. 2.

As described above, the photovoltaic module 1 includes a front face 2, generally made of transparent tempered glass with a thickness of approximately 3 mm, and a rear face 5, for example made of a polymer sheet, which is opaque or transparent, single-layer or multi-layer, having a Young's modulus greater than 400 MPa at room temperature.

The photovoltaic cells 4, electrically connected to each other by connecting conductors 6 and immersed between two front 3a and rear 3b layers of encapsulating material, both forming an encapsulating assembly 3 are located between the front 2 and rear 5 faces of the photovoltaic module 1.

FIG. 1A further shows an alternative embodiment of the example of FIG. 1 in which the photovoltaic cells 4 are of the IBC type, the connecting conductors 6 being only disposed against the rear faces of the photovoltaic cells 4.

Moreover, FIGS. 1 and 2 also show the junction box 7 of the photovoltaic module 1, intended to receive the wiring necessary for operating the module. Conventionally, this junction box 7 is made of plastic or rubber, and has complete sealing.

Usually, the method for producing the photovoltaic module 1 includes a step called vacuum lamination of the various layers described above, at a temperature greater than or equal to 120° C., or even 140° C., or even 150° C., and less than or equal to 170° C., typically comprised between 145 and 165° C., and for a duration of the lamination cycle generally of at least 10 minutes, or even 15 minutes.

During this lamination step, the layers 3a and 3b of encapsulating material melt and encompass the photovoltaic cells 4, at the same time as adhesion is created at all the interfaces between the layers, namely between the front face 2 and the front layer 3a of encapsulating material, the front layer 3a of encapsulating material and the front faces 4a of the photovoltaic cells 4, the rear faces 4b of the photovoltaic cells 4 and the rear layer 3b of encapsulating material, and the rear layer 3b of encapsulating material and the rear face 5 of the photovoltaic module 1. The photovoltaic module 1 obtained is then framed, typically by means of an aluminum profile.

Such a structure has now become a standard which has significant mechanical resistance thanks to the use of a thick glass front face 2 and the aluminum frame, allowing it, in particular and in the majority of cases, to comply with standards IEC 61215 and IEC 61730.

However, such a photovoltaic module 1 according to the conventional design of the prior art has the disadvantage of having a relatively high weight, in particular a weight per unit area of approximately 10 to 12 kg/m², and is thus not adapted for certain applications for which lightness is a priority.

This high weight of the photovoltaic module 1 comes mainly from the presence of thick glass, with a thickness of approximately 3 mm, to form the front face 2, the density of the glass being in fact high, of the order of 2.5 kg/m²/mm of thickness, and the aluminum frame. In order to be able to withstand the constraints during manufacturing, to have better mechanical resistance to impacts and also for safety reasons, for example due to the risk of cuts, the glass is tempered. However, the industrial infrastructure for thermal tempering is configured to treat glass which is at least 2 mm thick and technical difficulties also exist. Furthermore, the choice of having a glass thickness of approximately 3 mm is also related to a standardized mechanical resistance to pressure of 5.4 kPa. Ultimately, the glass alone thus represents almost 70% of the weight of the photovoltaic module 1, and more than 80% with the aluminum frame around the photovoltaic module 1.

Also, in order to achieve a significant reduction in the weight of a photovoltaic module to enable its use in applications requiring lightness, for example commercial roofs when the building structure is not designed for photovoltaic-related overload, there is a need to find an alternative solution to the use of thick glass on the front face of the module.

One possibility is to replace the glass front face with plastic materials while maintaining the usual architecture and implementation method with the primary goal of significantly reducing the surface weight. Thus, polymer sheets, such as polycarbonate (PC), polyethylene terephthalate (PET), polymethyl methacrylate (PMMA), polyvinylidene fluoride (PVDF), ethylene tetrafluoroethylene (ETFE), ethylene chlorotrifluoroethylene (ECTFE), or fluorinated ethylene propylene (FEP), can represent an alternative to glass. However, when only replacing glass with such a polymer sheet is considered, depending on the chosen thickness, the photovoltaic cell becomes very vulnerable to impact, mechanical load and differential expansions.

An alternative is the use of composite materials, including reinforcements, such as glass fibers, carbon fibers or natural fibers such as flax, hemp, among others, which complement the standard encapsulant to form a polymer/fiber type composite associated with a polymer protective film on the front face. The weight saving can be significantly important despite poorer transparency and uncertainty about performance aspects over periods greater than 20 years.

The elimination of glass on the front face of photovoltaic modules has been the subject of several patents or patent applications in the prior art. Examples include patent application FR 2 955 051 A1, American patent application US 2005/0178428 A1, or international applications WO 2008/019229 A2 and WO 2012/140585 A1. Other patents or patent applications have described the use of reinforcements alone or in composites, such as European patent application EP 2 863 443 A1, or international applications WO 2018/076525 A1, WO 2019/006764 A1, and WO 2019/006765 A1.

### DISCLOSURE OF THE INVENTION

There is therefore a need to design an alternative solution for a photovoltaic module designed to be lightweight in order to adapt to certain applications, while having sufficient mechanical properties allowing it to be resistant to impacts and mechanical load, and in particular to the IEC 61215 and IEC 61730 standards.

The invention therefore at least partially aims at overcoming the needs mentioned above and the disadvantages relating to the achievements of the prior art.

The invention thus relates, according to one of its aspects, to a photovoltaic module obtained from a stack comprising:
a first transparent layer forming the front face of the photovoltaic module, intended to receive a luminous flux,
a plurality of photovoltaic cells disposed side by side and electrically connected to each other,
an assembly encapsulating the plurality of photovoltaic cells, obtained by joining a front layer of an encapsulating material and a rear layer of an encapsulating material on either side of the photovoltaic cells, advantageously in direct contact therewith, the front layer of an encapsulating material being located between the first layer and the photovoltaic cells,
a second layer forming the rear face of the photovoltaic module, the encapsulating assembly and the plurality of photovoltaic cells being located between the first and second layers, characterized in that the first layer comprises:
   a front layer made of at least one polymer material, called a “polymer front layer”, and
   at least one front assembly comprising an interface front layer and a glass front layer, the glass front layer having a thickness less than or equal to 2 mm,
      said at least one front assembly being located between the polymer front layer and the encapsulating assembly, and the interface front layer of said at least one front assembly being located between the polymer front layer and the glass front layer,
      in that the front layer of an encapsulating material is formed by at least one layer including at least one polymer-type encapsulating material having a Young's modulus at 25° C. of strictly less than 50 MPa,
      and in that the rear layer of an encapsulating material is formed by at least one layer including at least one polymer-type encapsulating material having a Young's modulus at 25° C. of strictly greater than 150 MPa.

Advantageously, the invention allows the replacement of the standard thick glass of thickness of approximately 3 mm, usually used on the front face in a conventional photovoltaic module, by a combination of polymer layer(s) and thin glass layer(s). Thus, the use of thin glass(es) and polymer(s) allows to obtain a low mass and a transparency equivalent to a standard module. If the invention is compared to commercially available lightweight modules, the presence of thin glass in the structure allows better resistance to impacts and thermomechanical expansions compared to lightweight modules with transparent polymer films on the front face, and also to moisture penetration.

More advantageously, the use of polymer-type encapsulating material with reinforced mechanical properties, in particular for the rear layer of an encapsulating material of the encapsulating assembly, can allow to further improve the resistance to impacts, in particular hail-type impacts, on the photovoltaic module, and to protect the photovoltaic cells from possible mechanical damage.

The term “transparent” means that the first layer forming the front face of the photovoltaic module is at least partially transparent to visible light, allowing at least approximately 80% of this light to pass through.

In particular, the optical transparency, between 300 and 1200 nm, of the first layer forming the front face of the photovoltaic module, in particular the polymer front layer, can be greater than 80%. Similarly, the optical transparency, between 300 and 1200 nm, of the encapsulating assembly can be greater than 90%, as can that of the interface front layer.

Furthermore, by the term “encapsulating” or “encapsulated”, it is to be understood that the plurality of photovoltaic cells is disposed in a volume, for example hermetically sealed with respect to liquids, at least partly formed by at least two layers of encapsulating material(s), joined together after lamination to form the encapsulating assembly.

Indeed, initially, that is to say before any lamination operation, the encapsulating assembly is constituted by at least two layers of encapsulating material(s), called core layers, between which the plurality of photovoltaic cells is encapsulated. However, during the lamination operation of the layers, the layers of an encapsulating material melt to form, after the lamination operation, only a single solidified layer (or assembly) in which the photovoltaic cells are embedded.

Moreover, thanks to the invention, it may be possible to obtain a new type of lightweight photovoltaic module which, by using thin glass, can have a surface weight of less than 6 kg/m², or even 5 kg/m², while maintaining the optical transparency of the front face and ensuring good reliability of the photovoltaic module with low thermomechanical expansion and high durability. In addition, the use of the polymer front layer and interface layer(s) allows to protect the thin glass from impacts, in particular hailstone-type impacts.

The photovoltaic module according to the invention may also include one or more of the following features taken alone or in any possible technical combination.

The front layer of an encapsulating material may be formed by at least one layer including at least one polymer-type encapsulating material having a Young's modulus at 25° C. of strictly less than 50 MPa, in particular greater than 2 MPa and strictly less than 50 MPa, or even strictly less than 20 MPa, in particular comprised between 10 and 20 MPa.

In addition, the rear layer of an encapsulating material may be formed by at least one layer including at least one polymer-type encapsulating material having a Young's modulus at 25° C. of strictly greater than 200 MPa, in particular strictly greater than 200 MPa and less than 500 MPa, in particular comprised between 250 and 350 MPa.

Moreover, the elongation at break of the front layer of an encapsulating material and/or the rear layer of an encapsulating material may advantageously be at least greater than 200%.

The use of a rear layer of an encapsulating material with a high Young's modulus can provide increased resistance to hailstone-type impacts.

The glass front layer may advantageously have a thickness less than or equal to 1.5 mm, preferably comprised between 500 μm and 1 mm.

Moreover, the glass front layer can advantageously be made of non-tempered glass. In other words, the glass does not undergo any thermal or chemical tempering. Indeed, non-tempered glass can be less resistant to impacts, particularly those related to hailstone impacts. However, being placed between protective polymer layers, non-tempered glass can be protected from impacts. Non-tempered glass can also provide a moisture barrier for the photovoltaic cells. The use of non-tempered glass, rather than tempered glass, can significantly reduce costs so as to make the photovoltaic module adaptable to many applications.

In addition, the second layer may be made of at least one polymer material, in particular selected from: polycarbonate (PC), polymethyl methacrylate (PMMA), polyethylene terephthalate (PET), polypropylene (PP), polyamide (PA), a fluorinated polymer, in particular polyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers, among others. The choice of a second layer made of at least one polymer material may be preferred in the case where the final application of the photovoltaic module requires it to be superimposed on a rigid support.

Alternatively, due to the removal of the thick glass on the front face of the conventional photovoltaic module and the aluminum frame which can lead to a loss of mechanical strength of the module, and in order to maintain a rigid module, the rear face of the module can be designed to have sufficient mechanical rigidity.

In particular, according to a first possibility, the second layer can thus include:
a rear layer forming a rear panel made of composite material, comprising a main sub-layer, forming the core of the rear panel, and two covering sub-layers, each forming a plate of the rear panel, disposed on either side of the core so that the core is sandwiched between the two plates, the core of the rear panel including a cellular structure.

The core of the rear panel may include a cellular structure, for example in the form of a honeycomb, in particular made of metal, for example aluminum, polyimide, polycarbonate (PC), polypropylene (PP) or high-performance synthetic fibers, for example of the Nomex® type.

Alternatively, the core of the rear panel may include a cellular structure in the form of foam, in particular made of polyethylene terephthalate (PET), polyvinyl chloride (PVC) or polyurethane (PU).

Furthermore, the rear panel plates can be made of composite material, for example glass fiber/epoxy prepreg, made of metal, in particular aluminum, polycarbonate (PC), polymethyl methacrylate (PMMA) or from prepregs.

The rear panel plates can, if necessary, be covered with a single or multi-layer polymer film, for example of the Tedlar® type.

In addition, the rear panel may have a surface weight less than or equal to 3 kg/m², in particular less than or equal to 2 kg/m², in particular still less than or equal to 1 kg/m².

It should be noted that, rather than having a sandwich panel type rear face, the second layer may still include a rear layer including a cellular structure, without the use of covering sub-layers, for example a cellular structure of the cellular polycarbonate type.

According to a second possibility, the second layer can include:
a rear layer made of at least one polymer material, called a “polymer rear layer”, and
at least one rear assembly comprising an interface rear layer and a glass rear layer, the glass rear layer having in particular a thickness less than or equal to 2 mm, preferably still less than or equal to 1.5 mm, in particular comprised between 500 μm and 1 mm, and being in particular made of non-tempered glass,
   said at least one rear assembly being located between the polymer rear layer and the encapsulating assembly, and the interface rear layer of said at least one rear assembly being located between the polymer rear layer and the glass rear layer.

Thus, the second layer may be obtained according to a principle similar to that used for the first layer. In particular, the second layer may also include a combination of thin glass(es) and polymer(s). The second layer may or may not be identical to the first layer.

According to a third possibility, the second layer may include a layer of fiber-based reinforcements.

“Fiber-based reinforcement layer” means a layer including mainly organic and/or inorganic fibers, and preferably a layer consisting of organic and/or inorganic fibers. Advantageously, a fiber-based reinforcement layer allows mechanical reinforcement to the stack of layers intended to form the photovoltaic module. Before lamination, the fibers of a fiber-based reinforcement layer are preferably not impregnated, in particular with a polymer material. Such a reinforcement layer can be said to be fibered or woven. In particular, such a reinforcement layer is not a pre-impregnated layer, nor a composite layer.

The fiber-based reinforcement layer may include woven or non-woven fibers. It may further have a surface weight comprised between 20 g/m² and 1500 g/m², and preferably between 300 g/m² and 800 g/m². It may include glass, carbon, aramid fibers and/or natural fibers, in particular hemp, linen and/or silk, among others.

The glass used for the glass front layer and/or the glass rear layer may in particular be soda-lime glass, based on silica, calcium and sodium.

Moreover, the polymer front layer and/or the polymer rear layer may have a thickness comprised between 15 μm and 300 μm, in particular between 20 μm and 50 μm.

In addition, the polymer material of the polymer front layer and/or the polymer rear layer may be selected from: polycarbonate (PC), polymethyl methacrylate (PMMA), polyethylene terephthalate (PET), polyamide (PA), a fluorinated polymer, in particular polyvinyl fluoride (PVF) or polyvinylidene fluoride (PVDF), ethylene tetrafluoroethylene (ETFE), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers, among others.

Furthermore, the polymer front layer and/or the polymer rear layer may have a UV cutoff filter comprised between 320 nm and 450 nm, which corresponds to the wavelength for which the transmission rate is equal to 50%. In this way, the underlying layers can be protected from ultraviolet (UV) radiation aging and possibly from hydrolysis, which provides the photovoltaic module with an extended service life.

The interface front layer and/or the interface rear layer may allow bonding between the polymer front layer, respectively the polymer rear layer, and a glass layer, or between two glass layers.

The interface front layer and/or the interface rear layer may have a thickness comprised between 50 μm and 600 μm, preferably between 400 μm and 600 μm, or even between 400 μm and 500 μm.

The interface front layer and/or the interface rear layer may have a Young's modulus comprised between 2 and 300 MPa at 25° C., preferably between 2 and 250 MPa at 25° C., or even between 10 and 50 MPa at 25° C., or even between 2 and 50 MPa at 25° C., or even between 2 and 20 MPa at 25° C.

Furthermore, the interface front layer and/or the optional interface rear layer may be formed by at least one layer comprising at least one polymer-type encapsulating material selected from: acid copolymers, ionomers, poly (ethylene-vinyl acetate) (EVA), vinyl acetals, such as polyvinyl butyrals (PVB), polyurethanes, polyvinyl chlorides, polyethylenes, such as linear low density polyethylenes, polyolefin elastomers of copolymers, copolymers of α-olefins and α-, β-ethylenic carboxylic acid esters, such as ethylene-methyl acrylate copolymers and ethylene-butyl acrylate copolymers, silicone elastomers and/or elastomers based on crosslinked thermoplastic polyolefins, among others.

The front layer of an encapsulating material may be formed by at least one layer including at least one polymer-type encapsulating material selected from: poly (ethylene-vinyl acetate) (EVA), vinyl acetals, such as polyvinyl butyrals (PVB), polyurethanes, silicone elastomers, elastomers based on crosslinked thermoplastic polyolefin and/or elastomers based on crosslinked thermoplastic polyolefin (TPO), among others.

The rear layer of an encapsulating material may be formed by at least one layer including at least one polymer-type encapsulating material selected from: acid copolymers, ionomers, polyvinyl chlorides and/or polyethylenes, among others.

Preferably, the encapsulating material, and/or the thickness of the encapsulating material, of the encapsulating assembly, in particular of the front layer of an encapsulating material, is identical to the material, and/or the thickness of the material, of the interface front layer, and of the possible interface rear layer. In this way, it may be possible to facilitate the manufacturing method.

The front layer of an encapsulating material and/or the rear layer of an encapsulating material of the encapsulating assembly may have a thickness comprised between 200 μm and 600 μm, in particular comprised between 400 μm and 600 μm.

In addition, the photovoltaic cells may be selected from: homojunction or heterojunction photovoltaic cells based on monocrystalline silicon (c-Si) and/or multicrystalline silicon (mc-Si), and/or IBC type photovoltaic cells, and/or photovoltaic cells comprising at least one material from amorphous silicon (a-Si), microcrystalline silicon (μC-Si), cadmium telluride (CdTe), copper-indium selenide (CIS), copper-indium/gallium diselenide (CIGS), and perovskites, among others.

Moreover, the photovoltaic cells may have a thickness comprised between 1 and 300 μm, in particular between 1 and 200 μm, and advantageously between 70 μm and 160 μm.

The photovoltaic module may further include one or more junction boxes, intended to receive the wiring necessary for operating the photovoltaic module, which may be positioned on the front or rear face of the module, preferably on the front face.

Furthermore, the spacing between two neighboring, or consecutive or adjacent, photovoltaic cells may in certain configurations be greater than or equal to 1 mm, in particular comprised between 1 mm and 30 mm, and preferably equal to 2 mm. In other configurations, in particular of the “shingle” type, the neighboring, or consecutive or adjacent, photovoltaic cells may overlap.

According to a particular embodiment, the first layer may include:
a first front assembly comprising an interface front layer and a glass front layer, the glass front layer with a thickness less than or equal to 2 mm,
a second front assembly comprising an interface front layer and a glass front layer, the glass front layer with a thickness less than or equal to 2 mm, the first front assembly being located between the polymer front layer and the second front assembly, in turn located between the first front assembly and the encapsulating assembly.

The thickness of the glass front layer of the first front assembly and the thickness of the glass front layer of the second front assembly may be the same or different. In particular, the thickness of the glass front layer of the first front assembly may be greater than the thickness of the glass front layer of the second front assembly.

Furthermore, the second layer may include:
a rear layer made of at least one polymer material, called a “polymer rear layer”, and
a first rear assembly comprising an interface rear layer and a glass rear layer, the glass rear layer having in particular a thickness less than or equal to 2 mm, in particular less than or equal to 1.5 mm, in particular comprised between 500 μm and 1 mm, and being in particular made of non-tempered glass,
a second rear assembly comprising an interface rear layer and a glass rear layer, the glass rear layer having in particular a thickness less than or equal to 2 mm, in particular less than or equal to 1.5 mm, in particular comprised between 500 μm and 1 mm, and being in particular made of non-tempered glass, said first rear assembly being located between the polymer rear layer and the second rear assembly, in turn located between the first rear assembly and the encapsulating assembly.

In addition, the invention also relates, according to another of its aspects, to a method for producing a photovoltaic module, in particular as defined above, from a stack including:
a first transparent layer forming the front face of the photovoltaic module, intended to receive a luminous flux,
a plurality of photovoltaic cells disposed side by side and electrically connected to each other,
an assembly encapsulating the plurality of photovoltaic cells, obtained by joining a front layer of an encapsulating material and a rear layer of an encapsulating material on either side of the photovoltaic cells, the front layer of an encapsulating material being located between the first layer and the photovoltaic cells,
a second layer, the encapsulating assembly and the plurality of photovoltaic cells being located between the first and second layers, characterized in that the first layer comprises:
   a front layer made of at least one polymer material, called a “polymer front layer”, and
   at least one front assembly comprising an interface front layer and a glass front layer, the glass front layer having a thickness less than or equal to 2 mm,
      said at least one front assembly being located between the polymer front layer and the encapsulating assembly, and the interface front layer of said at least one front assembly being located between the polymer front layer and the glass front layer,
      the front layer of an encapsulating material being formed by at least one layer including at least one polymer-type encapsulating material having a Young's modulus at 25° C. of strictly less than 50 MPa,
      the rear layer of an encapsulating material being formed by at least one layer including at least one polymer-type encapsulating material having a Young's modulus at 25° C. of strictly greater than 150 MPa,
      and in that the method includes the step of hot and vacuum lamination of the constituent layers of the stack to obtain the photovoltaic module.

The hot and vacuum lamination step may in particular be carried out at a temperature greater than or equal to 120° C., or even 140° C., or even 150° C., and less than or equal to 170° C., or even 180° C., typically comprised between 130° C. and 180° C., or even between 145° C. and 165° C., and for a duration of the lamination cycle of at least 5 minutes, or even 10 minutes, or even 15 minutes, in particular comprised between 5 and 20 minutes.

Thus, this allows to achieve total encapsulation of the thin glass, allowing it to be protected against impacts.

The photovoltaic module and the production method according to the invention may include any one of the features previously stated, taken in isolation or in any technically possible combination with other features.

### BRIEF DESCRIPTION OF THE DRAWINGS

The invention may be better understood upon reading the detailed description which follows, of non-limiting examples of its implementation, as well as upon examining the schematic and partial figures of the appended drawing, in which:

FIG. 1 sectionally shows a conventional example of a photovoltaic module including crystalline photovoltaic cells,

FIG. 1A shows an alternative embodiment of the example of FIG. 1 in which the photovoltaic cells are of the IBC type,

FIG. 2 shows, in exploded view, the photovoltaic module of FIG. 1,

FIG. 3 illustrates, in perspective and in exploded view, a first exemplary embodiment of a photovoltaic module in accordance with the invention,

FIG. 3A sectionally illustrates an example of a rear layer used as a variant for the photovoltaic module shown in FIG. 3,

FIG. 4 illustrates, in perspective and in exploded view, a second exemplary embodiment of a photovoltaic module in accordance with the invention,

FIG. 5 illustrates, in perspective and in exploded view, a third exemplary embodiment of a photovoltaic module in accordance with the invention, and

FIG. 6 illustrates, in perspective and in exploded view, a fourth exemplary embodiment of a photovoltaic module in accordance with the invention.

Throughout these figures, identical references may designate identical or similar elements.

In addition, the different parts represented in the figures are not necessarily on a uniform scale, in order to make the figures more readable.

### DETAILED DESCRIPTION OF THE INVENTION

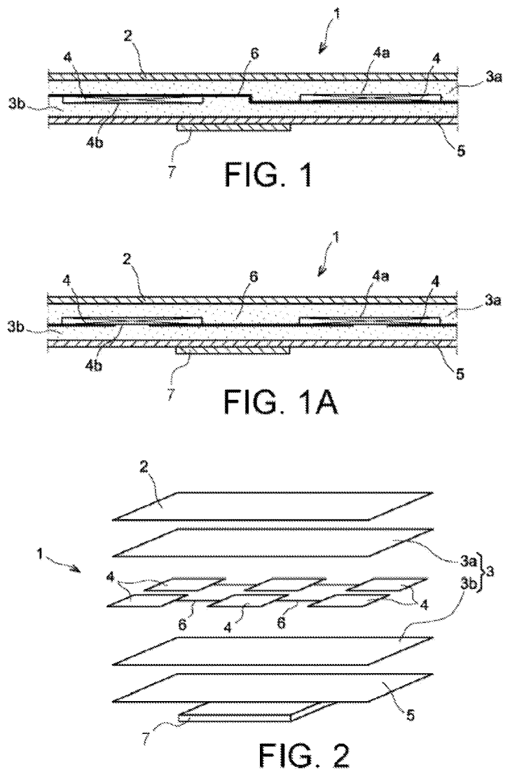

FIGS. 1, 1A and 2 have already been described in the section relating to the prior art.

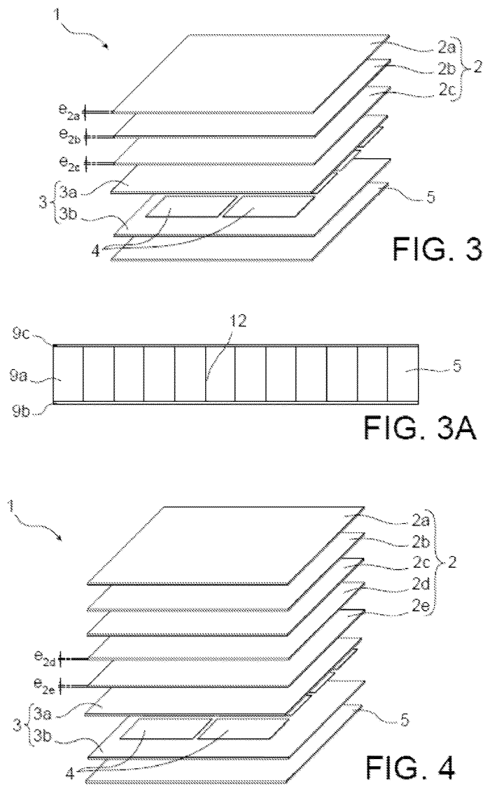

FIGS. 3 to 6 illustrate four distinct embodiments of photovoltaic modules 1 in accordance with the invention.

It is considered here that the photovoltaic cells 4, interconnected by soldered tinned copper strips, similar to those shown in FIGS. 1, 1A and 2, are “crystalline” cells, that is to say that they include mono or multicrystalline silicon, and that they have a thickness comprised between 1 and 250 μm.

In addition, the polymer front layer 2a may be a fluorinated polymer film, with a thickness of the order of 50 μm, in particular made of ethylene tetrafluoroethylene (ETFE), for example of the Saint-Gobain ChemFilm® ETFE-E2 type.

The interface layers 2b, 2d and 5b may include a polymer encapsulating film, for example of type A formed by a thermoplastic elastomer based on polyolefin (TPO) with a Young's modulus at 25° C. of 18 MPa or of type B formed by an ionically crosslinked thermoplastic copolymer, for example of the Ionomer type, with a Young's modulus at 25° C. of 285 MPa. The thickness may be comprised between 500 and 600 μm, and be for example of the order of 500 μm. In particular, for a type A polymer encapsulant film, it can be Borealis Quentys® BPO8828UV, and for a type B polymer encapsulant film, it can be KuranSeal-ES® (PV8729D/UV CUT) from Kurabo, with a thickness of 500 μm.

Glass layers 2c, 2e and 5c may include thin, non-tempered glass with a thickness comprised between 500 and 1000 μm, for example of the order of 950 μm.

The second layer 5, when produced in the form of a polymer multilayer, can integrate an aluminized layer.

The second layer 5, when in the form of a rear panel 5, may include a polypropylene honeycomb core 9a and composite skins or plates 9b, 9c made of glass-reinforced polypropylene with a thickness, for example, comprised between 6 and 10 mm, for example of the Nidapan® 8 GR 600 type with a thickness of 10 mm.

Of course, these choices are in no way limiting.

For all the stacking examples described with reference to FIGS. 3 to 6, tests were carried out against mechanical impacts of the hailstone type, 25 mm in diameter, for energy levels of 2 J representative of the certification standard IEC 61215. The mechanical impact tests were carried out by gluing the photovoltaic module 1 to a rigid support representative of that of flat roofs, terraces, or commercial buildings.

The results demonstrated the increased improvement in impact resistance with the use of an encapsulant having enhanced mechanical properties at the rear layer of an encapsulating material of the encapsulating assembly.

In order to describe the different configurations considered, reference is first made to FIG. 3 which illustrates, in perspective and in exploded view, a first exemplary embodiment of a photovoltaic module 1 in accordance with the invention.

It should be noted that FIG. 3 corresponds to an exploded view of the photovoltaic module 1 before the lamination step of the method according to the invention. Once the lamination step has been carried out, ensuring hot and vacuum pressing, the different layers are in reality in contact with each other, and in particular interpenetrated with each other.

The photovoltaic module 1, or more precisely the stack intended to form the photovoltaic module 1, thus includes a first layer 2 forming the front face of the photovoltaic module 1 and intended to receive a luminous flux, a plurality of photovoltaic cells 4 disposed side by side and electrically connected to each other, an assembly 3 encapsulating the plurality of photovoltaic cells 4, comprising a front layer 3a of encapsulating material and a rear layer 3b of encapsulating material located on either side of the photovoltaic cells 4, and a second layer 5 forming the rear face of the photovoltaic module 1.

It should further be noted that a junction box 7 may be disposed on the front face or else on the rear face, as shown in FIGS. 1, 1A and 2, of the photovoltaic module 1.

In accordance with the invention, and in a manner common to the examples of FIGS. 3 to 6, the first layer 2 includes a front layer made of a polymer material 2a, called “polymer front layer 2a”, and a first front assembly 2b, 2c comprising an interface front layer 2b and a glass front layer, advantageously made of non-tempered glass 2c.

Advantageously, the glass front layer 2c has a thickness e_{2c} less than or equal to 2 mm, or even less than or equal to 1.5 mm, and in particular comprised between 500 μm and 1 mm.

In this example, the second layer 5 is made of at least one polymer material of the “backsheet” type. It may include a polymer material selected from: polycarbonate (PC), polymethyl methacrylate (PMMA), polyethylene terephthalate (PET), polypropylene (PP), polyamide (PA), a fluorinated polymer, in particular polyvinyl fluoride (PVF) or tetrafluoroethylene (ETFE), ethylene polyvinylidene fluoride (PVDF), ethylene chlorotrifluoroethylene (ECTFE), polytetrafluoroethylene (PTFE), polychlorotrifluoroethylene (PCTFE), fluorinated ethylene propylene (FEP) and/or a multilayer film comprising one or more of the aforementioned polymers. Advantageously, it is produced in the form of a polymer multilayer and includes an aluminized layer.

Moreover, in this example, the front layer 3a of encapsulating material and the interface front layer 2b are all type A encapsulant films as previously described.

On the other hand, in order to obtain increased impact resistance, the rear layer 3b of encapsulating material is a type B encapsulant film as described above. Thus, its mechanical properties are enhanced.

More generally, in all the examples described here with reference to FIGS. 3 to 6, the invention provides for having a front layer 3a of encapsulating material with a Young's modulus at 25° C. of strictly less than 50 MPa, or even strictly less than 20 MPa, or even greater than 2 MPa and strictly less than 50 MPa, or even comprised between 10 and 20 MPa, and a rear layer of an encapsulating material with a Young's modulus at 25° C. of strictly greater than 150 MPa, preferably strictly greater than 200 MPa, preferably still strictly greater than 200 MPa and less than 500 MPa, or even comprised between 250 and 350 MPa. In particular, the front layer 3a of encapsulating material is a type A encapsulant film while the rear layer 3b of encapsulating material is a type B encapsulant film.

By using a type B encapsulant film for the rear layer 3b of encapsulating material, rather than using a type A encapsulant film, any breakage phenomenon of the glass and the photovoltaic cells 4 can thus be avoided.

It should be noted that the second layer 5 may alternatively be formed by a rear panel 5 made of composite material, comprising a main sub-layer, forming the core 9a of the rear panel 5, and two covering sub-layers, each forming a plate 9b, 9c of the rear panel 5, disposed on either side of the core 9a so that the core 9a is sandwiched between the two plates 9b, 9c, the core 9a of the rear panel 5 including a cellular structure 12.

FIG. 3A shows, schematically sectionally in more detail, this variant of the second layer 5 formed in the example of FIG. 3. It should also be noted that alternatively, the second layer 5 could include a layer of reinforcements based on fibers, woven or not, in particular glass fibers, carbon fibers, aramid fibers and/or natural fibers, in particular hemp, linen and/or silk, among others.

The photovoltaic module 1 is obtained by means of a single vacuum hot lamination step, for example at a temperature of approximately 150° C. for approximately 15 minutes. It has a surface weight of 4.4 kg/cm².

It has been described previously that the front layer 3a of encapsulating material and the interface front layer 2b use type A encapsulant films while the rear layer 3b of encapsulating material uses a type B encapsulant film. It should be noted that the interface front layer 2b may also use a type B rather than type A encapsulant film if it is desired to further improve the impact resistance of the photovoltaic module 1.

Moreover, FIG. 4 illustrates a second exemplary embodiment in accordance with the invention.

In this example, unlike that of FIG. 3, the first layer 2 also includes a second front assembly 2d, 2e comprising an interface front layer 2d and a glass front layer, advantageously made of non-tempered glass 2e. The glass front layer 2e has a thickness e₂ₑ less than or equal to 2 mm, or even less than or equal to 1.5 mm, and in particular comprised between 500 μm and 1 mm. In other words, this exemplary embodiment provides for doubling the thickness of glass in the first layer 2. A photovoltaic module 1 with a surface weight equal to 6 kg/cm² is then obtained. The impact resistance of the photovoltaic module 1 is further improved.

In addition, the first interface front layer 2b and the encapsulation front layer 3a are formed by type A encapsulant films, while the second interface front layer 2d and the encapsulation rear layer 3b are formed by type B encapsulant films.

In the example of FIG. 4, the first glass front layer 2b and the second glass front layer 2e have the same thickness. Alternatively, it is possible to use different glass thicknesses, for example a thickness e_{2b} of the order of 500 μm and a thickness e₂ₑ of the order of 300 μm. Thus, if it is considered that 800 μm of glass can meet the need for resistance of the cells 4 to impacts, it is possible to use for example a glass of 500 μm and a glass of 300 μm.

Indeed, it is known that elastomeric materials have vibration and impact damping properties. The alternation of rigid materials with elastomeric materials will thus allow to modify the speed of propagation of impact waves, because the speed of an impact wave is directly proportional to the Young's modulus and Poisson's ratio of the material used. The insertion of flexible elastomeric layers, between layers of more rigid materials, therefore allows to slow down the propagation of impact waves. In addition, at each interface encountered, the impact wave can be transmitted and/or reflected in part. The repetition of the alternation of these polymer layers having different Young's moduli therefore allows on the one hand to slow down the impact waves and on the other hand to reduce the intensity of the latter which reach the photovoltaic cells.

Also, for an equivalent quantity of glass, it may be more interesting to distribute this quantity between at least two layers of glass of different thicknesses instead of a single layer of glass.

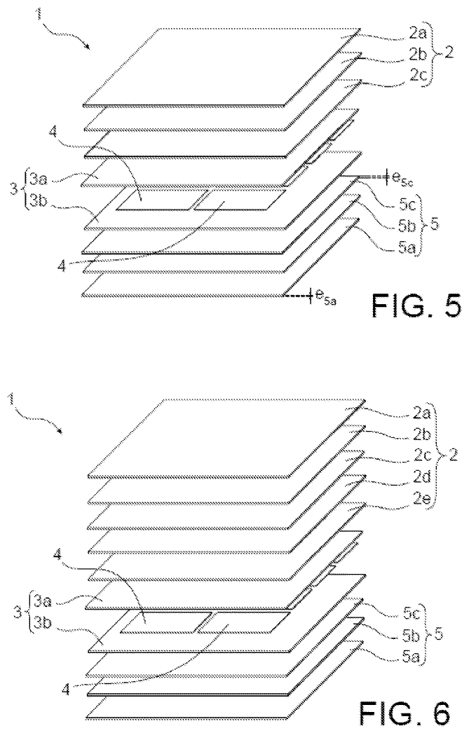

Furthermore, FIG. 5 illustrates a third exemplary embodiment whose principle is to use the same encapsulation architecture on the rear face as on the front face, in a symmetrical manner. It is thus possible to obtain a bifacial and lightweight photovoltaic module 1.

Thus, the second layer 5 here includes a rear layer made of a polymer material 5a, called “polymer rear layer 5a”, and a first rear assembly 5b, 5c comprising an interface rear layer 5b and a glass rear layer, which is preferably not tempered 5c.

The glass rear layer 5c has a thickness e_{5c} of 550 μm, and the glass front layer 2c also has a thickness e_{2c} of 550 μm.

The interface front layer 2b, the interface rear layer 5b and the encapsulation rear layer 3b are herein type B encapsulant films, while the encapsulation front layer 3a is a type A encapsulant film.

Moreover, FIG. 6 illustrates a fourth exemplary embodiment corresponding to a variant of the example of FIG. 5 in which the use of thin glasses preferably not tempered on the front face and on the rear face is carried out asymmetrically.

In particular, two thin glasses 2c and 2e can be used as the front face of the same or different thicknesses, and a thin glass 5c can be used as the rear face. More specifically here, a first glass front layer 2c has a thickness e_{2c} of 500 μm, a second glass front layer 2e has a thickness e₂ₑ of 300 μm, and a first glass rear layer 5c has a thickness e_{5c} of 550 μm.

In addition, the first interface front layer 2b, the second interface front layer 2d, the interface rear layer 5b, and the encapsulation rear layer 3b are herein type B encapsulant films while the encapsulation front layer 3a is a type A encapsulant film.

In all the examples described above, the polymer front layer 2a and the polymer rear layer 5a have a thickness e₂ₐ, e₅ₐ of the order of 50 μm.

The interface front layers 2b, 2d and the interface rear layer 5b have a thickness e_{2b}, e_{2d}, e_{5b} of the order of 600 μm.

Of course, the invention is not limited to the exemplary embodiments which have just been described. Various modifications can be made thereto by the person skilled in the art.

In particular, these exemplary embodiments can be produced in various variants using one or more of the materials mentioned above to form the first layer 2 and the second layer 5.

1-17. (canceled)

18. A photovoltaic module obtained from a stack comprising:
a first transparent layer forming the front face of the photovoltaic module, intended to receive a luminous flux,
a plurality of photovoltaic cells disposed side by side and electrically connected to each other,
an assembly encapsulating the plurality of photovoltaic cells, obtained by joining a front layer of an encapsulating material and a rear layer of an encapsulating material on either side of the photovoltaic cells, the front layer of an encapsulating material being located between the first layer and the photovoltaic cells,
a second layer forming the rear face of the photovoltaic module, the encapsulating assembly and the plurality of photovoltaic cells being located between the first and second layers,
wherein the first layer comprises:
a front layer made of at least one polymer material, called “polymer front layer”, and
at least one front assembly comprising an interface front layer and a glass front layer, the glass front layer having a thickness less than or equal to 2 mm,
said at least one front assembly being located between the polymer front layer and the encapsulating assembly, and the interface front layer of said at least one front assembly being located between the polymer front layer and the glass front layer,
wherein the front layer of an encapsulating material is formed by at least one layer including at least one polymer-type encapsulating material having a Young's modulus at 25° C. comprised between 2 and 20 MPa,
and wherein the rear layer of an encapsulating material is formed by at least one layer including at least one polymer-type encapsulating material having a Young's modulus at 25° C. of strictly greater than 200 MPa.

19. The module according to claim 18, wherein the front layer of an encapsulating material is formed by at least one layer including at least one polymer-type encapsulating material having a Young's modulus at 25° C. comprised between 10 and 20 MPa, and wherein the rear layer of an encapsulating material is formed by at least one layer including at least one polymer-type encapsulating material having a Young's modulus at 25° C. of strictly greater than 200 MPa and less than 500 Mpa.

20. The module according to claim 19, wherein the rear layer of an encapsulating material is formed by at least one layer including at least one polymer-type encapsulating material having a Young's modulus at 25° C. comprised between 250 and 350 MPa.

21. The module according to claim 18, wherein the glass front layer has a thickness less than or equal to 1.5 mm.

22. The module according to claim 21, wherein the glass front layer has a thickness comprised between 500 μm and 1 mm.

23. The module according to claim 18, wherein the glass front layer is made of non-tempered glass.

24. The module according to claim 18, wherein the second layer is made of at least one polymer material.

25. The module according to claim 24, wherein the second layer is made of at least one polymer material selected from: polycarbonate, polymethyl methacrylate, polyethylene terephthalate, polypropylene, polyamide, a fluorinated polymer, ethylene tetrafluoroethylene, ethylene chlorotrifluoroethylene, polytetrafluoroethylene, polychlorotrifluoroethylene, fluorinated ethylene propylene and/or a multilayer film comprising one or more of the aforementioned polymers.

26. The module according to claim 18, wherein the second layer includes:
a rear layer forming a rear panel made of composite material, comprising a main sub-layer, forming the core of the rear panel, and two covering sub-layers, each forming a plate of the rear panel, disposed on either side of the core so that the core is sandwiched between the two plates, the core of the rear panel including a cellular structure.

27. The module according to claim 18, wherein the second layer includes:
a rear layer made of at least one polymer material, called “polymer rear layer”, and
at least one rear assembly comprising an interface rear layer and a glass rear layer,
said at least one rear assembly being located between the polymer rear layer and the encapsulating assembly, and the interface rear layer of said at least one rear assembly being located between the polymer rear layer and the glass rear layer.

28. The module according to claim 27, wherein the glass rear layer has a thickness less than or equal to 2 mm.

29. The module according to claim 18, wherein the second layer includes a layer of reinforcements based on fibers.

30. The module according to claim 29, wherein the second layer includes a layer of reinforcements based on glass fibers, carbon fibers, aramid fibers and/or natural fibers.

31. The module according to claim 18, wherein the polymer front layer and/or the polymer rear layer have a thickness comprised between 15 μm and 300 μm.

32. The module according to claim 18, wherein the interface front layer and/or the interface rear layer have a thickness comprised between 50 μm and 600 μm.

33. The module according to claim 18, wherein the interface front layer and/or the optional interface rear layer are formed by at least one layer including at least one polymer-type encapsulating material selected from: acid copolymers, ionomers, poly (ethylene-vinyl acetate), vinyl acetals, polyurethanes, polyvinyl chlorides, polyethylenes, polyolefin elastomers of copolymers, copolymers of α-olefins and α-, β-ethylenic carboxylic acid esters, silicone elastomers and/or elastomers based on crosslinked thermoplastic polyolefin.

34. The module according to claim 18, wherein the front layer of an encapsulating material is formed by at least one layer including at least one polymer-type encapsulating material selected from: poly (ethylene-vinyl acetate), vinyl acetals, polyurethanes, silicone elastomers, elastomers based on crosslinked thermoplastic polyolefin and/or elastomers based on crosslinked thermoplastic polyolefin.

35. The module according to claim 18, wherein the rear layer of an encapsulating material is formed by at least one layer including at least one polymer-type encapsulating material selected from: acid copolymers, ionomers, polyvinyl chlorides and/or polyethylenes.

36. The module according to claim 18, wherein the first layer includes:
a first front assembly comprising an interface front layer and a glass front layer, the glass front layer with a thickness less than or equal to 2 mm,
a second front assembly comprising an interface front layer and a glass front layer, the glass front layer with a thickness less than or equal to 2 mm,
the first front assembly being located between the polymer front layer and the second front assembly, in turn located between the first front assembly and the encapsulating assembly.

37. The module according to claim 36, wherein the thickness of the glass front layer of the first front assembly and the thickness of the glass front layer of the second front assembly are different, the thickness of the glass front layer of the first front assembly being greater than the thickness of the glass front layer of the second front assembly.

38. The module according to claim 18, wherein the second layer includes:
a rear layer made of at least one polymer material, called “polymer rear layer”, and
a first rear assembly comprising an interface rear layer and a glass rear layer,
a second rear assembly comprising an interface rear layer and a glass rear layer,
said first rear assembly being located between the polymer rear layer and the second rear assembly, in turn located between the first rear assembly and the encapsulating assembly.

39. The module according to claim 38, wherein the glass rear layer has a thickness less than or equal to 2 mm.

40. A method for producing a photovoltaic module according to claim 18, from a stack including:
a first transparent layer forming the front face of the photovoltaic module, intended to receive a luminous flux,
a plurality of photovoltaic cells disposed side by side and electrically connected to each other,
an assembly encapsulating the plurality of photovoltaic cells, obtained by joining a front layer of an encapsulating material and a rear layer of an encapsulating material on either side of the photovoltaic cells, the front layer of an encapsulating material being located between the first layer and the photovoltaic cells,
a second layer, the encapsulating assembly and the plurality of photovoltaic cells being located between the first and second layers,
wherein the first layer comprises:
a front layer made of at least one polymer material, called “polymer front layer”, and
at least one front assembly comprising an interface front layer and a glass front layer, the glass front layer with a thickness less than or equal to 2 mm,
said at least one front assembly being located between the polymer front layer and the encapsulating assembly, and the interface front layer of said at least one front assembly being located between the polymer front layer and the glass front layer,
the front layer of an encapsulating material being formed by at least one layer comprising at least one polymer-type encapsulating material having a Young's modulus at 25° C. comprised between 2 and 20 MPa,
and the rear layer of an encapsulating material being formed by at least one layer including at least one polymer-type encapsulating material having a Young's modulus at 25° C. of strictly greater than 200 MPa,
and wherein the method includes the step of hot and vacuum lamination of the constituent layers of the stack to obtain the photovoltaic module.
